(19) United States
(12) Patent Application Publication
(10) Pub. No.: US 2013/0196078 A1
(43) Pub. Date: Aug. 1, 2013

(54) Multi-Chamber Substrate Processing System

(71) Applicants: Joseph Yudovsky, Campbell, CA (US); Nag B. Patibandla, Pleasanton, CA (US); Pravin K. Narwankar, Sunnyvale, CA (US); Li-Qun Xia, Cupertino, CA (US); Toshiaki Fujita, Sakura City (JP); Ralf Hofmann, Soquel, CA (US); Jeonghoon Oh, San Jose, CA (US); Srinivas Satya, Sunnyvale, CA (US); Banqiu Wu, Sunnyvale, CA (US)

(72) Inventors: Joseph Yudovsky, Campbell, CA (US); Nag B. Patibandla, Pleasanton, CA (US); Pravin K. Narwankar, Sunnyvale, CA (US); Li-Qun Xia, Cupertino, CA (US); Toshiaki Fujita, Sakura City (JP); Ralf Hofmann, Soquel, CA (US); Jeonghoon Oh, San Jose, CA (US); Srinivas Satya, Sunnyvale, CA (US); Banqiu Wu, Sunnyvale, CA (US)

(21) Appl. No.: 13/754,771

(22) Filed: Jan. 30, 2013

Related U.S. Application Data
(60) Provisional application No. 61/593,215, filed on Jan. 31, 2012.

(51) Int. Cl. C23C 16/458

(52) U.S. Cl. CPC C23C 16/4584
USPC 427/535; 118/730; 118/723 R; 427/255.5

(57) ABSTRACT

A substrate processing system for processing multiple substrates is provided and generally includes at least one substrate processing platform and at least one substrate staging platform. The substrate processing platform includes a rotary track system capable of supporting multiple substrate support assemblies and continuously rotating the substrate support assemblies, each carrying a substrate thereon. Each substrate is positioned on a substrates support assembly disposed on the rotary track system and being processed through at least one shower head station and at least one buffer station, which are positioned atop the rotary track system of the substrate processing platform. Multiple substrates disposed on the substrate support assemblies are processed in and out the substrate processing platform. The substrate staging platform includes at least one dual-substrate processing station, each dual-substrate processing station includes two substrate support assemblies for supporting two substrates thereon.

### CROSS-REFERENCE TO RELATED APPLICATIONS

This application claims priority to U.S. Provisional Application No. 61/593,215, filed Jan. 31, 2012.

### BACKGROUND

Embodiments of the present invention generally relate to an apparatus for processing substrates. More particularly, the invention relates to a batch processing platform for performing atomic layer deposition (ALD) and chemical vapor deposition (CVD) on substrates.

The process of forming semiconductor devices is commonly conducted in substrate processing platforms containing multiple chambers. In some instances, the purpose of a multi-chamber processing platform or cluster tool is to perform two or more processes on a substrate sequentially in a controlled environment. In other instances, however, a multiple chamber processing platform may only perform a single processing step on substrates; the additional chambers are intended to maximize the rate at which substrates are processed by the platform. In the latter case, the process performed on substrates is typically a batch process, wherein a relatively large number of substrates, e.g. 25 or 50, are processed in a given chamber simultaneously. Batch processing is especially beneficial for processes that are too time-consuming to be performed on individual substrates in an economically viable manner, such as for ALD processes and some chemical vapor deposition (CVD) processes.

The effectiveness of a substrate processing platform, or system, is often quantified by cost of ownership (COO). The COO, while influenced by many factors, is largely affected by the system footprint, i.e., the total floor space required to operate the system in a fabrication plant, and system throughput, i.e., the number of substrates processed per hour. Footprint typically includes access areas adjacent the system that are required for maintenance. Hence, although a substrate processing platform may be relatively small, if it requires access from all sides for operation and maintenance, the system's effective footprint may still be prohibitively large.

The semiconductor industry's tolerance for process variability continues to decrease as the size of semiconductor devices shrink. To meet these tighter process requirements, the industry has developed a host of new processes which meet the tighter process window requirements, but these processes often take a longer time to complete. For example, for forming a copper diffusion barrier layer conformally onto the surface of a high aspect ratio, 65 nm or smaller interconnect feature, it may be necessary to use an ALD process. ALD is a variant of CVD that demonstrates superior step coverage compared to CVD. ALD is based upon atomic layer epitaxy (ALE) that was originally employed to fabricate electroluminescent displays. ALD employs chemisorption to deposit a saturated monolayer of reactive precursor molecules on a substrate surface. This is achieved by cyclically alternating the pulsing of appropriate reactive precursors into a deposition chamber. Each injection of a reactive precursor is typically separated by an inert gas purge to provide a new atomic layer to previous deposited layers to form an uniform material layer on the surface of a substrate. Cycles of reactive precursor and inert purge gases are repeated to form the material layer to a desired thickness. The biggest drawback with ALD techniques is that the deposition rate is much lower than typical CVD techniques by at least an order of magnitude. For example, some ALD processes can require a chamber processing time from about 10 to about 200 minutes to deposit a high quality layer on the surface of the substrate. In choosing such ALD and epitaxial processes for better device performance, the cost to fabricate devices in a conventional single substrate processing chamber would increase due to very low substrate processing throughput. Hence, when implementing such processes, a multi-chamber, multi-substrate processing approach is needed to be economically feasible.

Therefore, there is a need for a multi-chamber substrate system integrated with a multi-substrate ALD processing platform to maximize processing throughput.

### SUMMARY

Embodiments of the present invention provide a multi-chamber substrate processing system integrated with a multi-substrate processing platform with minimized footprint, ease of carrying multiple process steps, and high throughput. In one embodiment, a multi-substrate processing platform for processing a plurality of substrates is provided and includes one or more gas distribution assemblies, a rotary track mechanism, and a dual-blade transfer robot. The rotary track mechanism is positioned at a distance below the one or more gas distribution assemblies for rotating a plurality of substrate carriers. In one aspect, each substrate carrier is adapted to carry at least one substrate thereon and to be rotationally moved by the rotary track mechanism at a first rotating speed such that the plurality of substrates disposed on the plurality of substrate carriers are moved under and continuously passed through the one or more gas distribution assemblies. In another aspect, each substrate carrier disposed on the rotary track mechanism is capable of self-rotating at a second rotating speed. The rotary track mechanism is capable of concurrently receiving at least two substrates, which are being transferred onto the rotary track mechanism by the dual-blade transfer robot. The dual-blade transfer robot is capable of carrying at least two substrates and concurrently transferring the two substrates onto and out of two substrate carriers disposed on the rotary track mechanism.

In another embodiment, a substrate processing system is provided for processing a plurality of substrates and includes a processing platform and a transfer chamber connected to the processing platform. The processing platform includes one or more gas distribution assemblies and a rotary track mechanism, positioned at a first distance below the one or more gas distribution assemblies, being capable of concurrently receiving at least two substrate carriers, and being configured to rotate at a first rotating speed such that the plurality of substrates disposed on the plurality of substrate carriers are rotated under and passed through the one or more gas distribution assemblies. The transfer chamber includes a dual blade transfer robot disposed therein. The dual-blade transfer robot is capable of carrying two substrates and concurrently transferring the two substrates onto and out of two substrate carriers disposed on the rotary track mechanism. In one aspect, the transfer chamber is connected to one or more dual-substrate processing stations.

In still another embodiment, a substrate processing system for processing a plurality of substrates includes a processing platform and a transfer chamber, where the processing platform includes a substrate support assembly, one gas distribution assemblies, and a rotary track mechanism supporting the substrate support assembly and being disposed at a first distance below the one or more gas distribution assemblies. The substrate support assembly includes a multi-substrate receiving surface capable of supporting the plurality of substrates and concurrently receiving at least two substrates thereon, which are being transferred by a dual blade transfer robot disposed in the transfer chamber. Thus, two substrates are concurrently transferred onto and out of the multi-substrate receiving surface of the substrate support assembly disposed above the rotary track mechanism. In another embodiment, the substrate processing system may further include one or more dual substrate processing stations connected to the transfer chamber. In one configuration, the substrate processing system further comprises dual-substrate load lock chambers.

Methods for batch processing a plurality of substrates are also provided. One method include loading two of the plurality of substrates onto a rotary track mechanism of a batch processing platform, continuously rotating the rotary track mechanism such that the plurality of the substrates are moved under and passed through one or more gas distribution assemblies positioned at a first distance above the rotary track mechanism, and unloading the two substrates from the rotary track mechanism of the batch processing platform.

Another method for batch processing a plurality of substrates includes loading two of the plurality of substrates onto two substrate carriers disposed on a rotary track mechanism of a batch processing platform, continuously rotating the rotary track mechanism such that the plurality of the substrates are moved under and passed through one or more gas distribution assemblies positioned at a first distance above the rotary track mechanism, and unloading the two substrates from the rotary track mechanism of the batch processing platform.

Still, another method for batch processing a plurality of substrates, includes loading two of the plurality of substrates onto a rotary track mechanism of a batch processing platform using a dual-blade transfer robot capable of carrying and concurrently transferring the two substrates onto and out of the rotary track mechanism, continuously rotating the rotary track mechanism such that the plurality of the substrates are moved under and passed through one or more gas distribution assemblies positioned at a first distance above the rotary track mechanism, and unloading the two substrates from the rotary track mechanism of the batch processing platform.

In additional embodiments, the substrate processing platform further comprises one or more treatment stations rotationally disposed between the one or more gas distribution assemblies. In some embodiments, the one or more treatment stations comprise plasma processing stations. In one or more embodiments, there are two or more gas distribution assemblies rotationally disposed adjacent the rotary track mechanism.

In further embodiments, the substrate processing platform further comprises a set of first treatment stations and a set of second treatment stations, so that a first treatment station and a second treatment station are rotationally positioned adjacent the rotary track mechanism between each of the gas distribution assemblies. In one or more embodiments, one or more treatment stations are rotationally disposed between the one or more gas distribution assemblies. In some embodiments, the one or more treatment stations comprise plasma processing stations. In one or more embodiments, the processing platform comprises two or more gas distribution assemblies rotationally disposed adjacent the rotary track mechanism. In some embodiments, the apparatus further comprises a set of first treatment stations and a set of second treatment stations, so that a first treatment station and a second treatment station are rotationally positioned adjacent the rotary track mechanism between each of the gas distribution assemblies.

Additional embodiments of the invention are directed to methods of processing a plurality of substrates. A plurality of substrates are loaded onto a rotary track mechanism in a processing chamber comprising a plurality of gas distribution assemblies so that the substrates are rotationally disposed about the interior of the processing chamber adjacent a rotary track mechanism and positioned in substantially equivalent starting positions. The rotary track mechanism is rotated so that each substrate moves from a first side of a gas distribution assembly to a second side of the gas distribution assembly so that layer is deposited on a surface of the substrate by a plurality of gas streams provided by the gas distribution assembly. The rotary track mechanism is continued to be rotated so that each substrate moves from the first side of a gas distribution assembly to the second side of the gas distribution assembly until a film of desired thickness is formed. The plurality of substrates are unloaded from the processing chamber so that each substrate has experienced substantially the same processing environment. Some embodiments further comprise stopping the rotary track mechanism after each substrate has passed to the second side of the gas distribution assembly so that each substrate is positioned adjacent a plasma treatment station and plasma treating the film formed on the surface of the substrate.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic plan view of a substrate processing system with four gas distribution assemblies and four intermediate treatment stations in accordance with one or more embodiment of the invention;

FIGS. 2A through 2C are schematic plan views of cluster tools with substrate processing systems having various numbers of gas distribution assemblies;

FIG. 3 shows a schematic plan view of a substrate processing system including three processing groups, each processing group including a gas distribution assembly, a first treatment station and a second treatment station;

FIG. 4A is a schematic plan view of a substrate processing system configured with a processing platform, a transfer chamber, and additional chambers for continuously loading, unloading and processing multiple substrates in accordance with one embodiment of the invention.

FIG. 4B is a schematic plan view of a substrate processing system configured with a processing platform, two transfer chambers, and additional chambers for continuously loading, unloading and processing multiple substrates in accordance with another embodiment of the invention.

FIG. 5 is a schematic plan view of a transfer chamber connected to a processing platform with multiple shower head stations and multiple buffer stations and illustrates a plurality of substrates being rotationally disposed below the gas distribution assemblies of the multiple shower head stations in accordance with one or more embodiments of the invention.

FIG. 6 is a side view of a gas distribution assembly in a shower head station, illustrating the side facing the surface of the substrate and having multiple open gas channels in accordance with one or more embodiments of the invention.

FIG. 7 is a partial cross-sectional side view of a gas distribution assembly in a processing station with the substrate disposed below in accordance with one or more embodiments of the invention.

FIG. 8 is a partial cross-sectional side view of a processing platform, showing two substrates disposed below two gas distribution assemblies of two processing stations on the surface of a rotary substrate support assembly.

### DETAILED DESCRIPTION

A multi-chamber substrate processing system is provided to maximize processing throughput and maintain processing uniformity. A multi-chamber substrate processing system may include a processing platform for ALD and CVD applications and one or more additional process chambers for other CVD, PVD, etch, cleaning, heating, annealing, and/or polishing processes. In one embodiment, throughput is improved by using a rotary track mechanism within the processing platform such that a plurality of substrates can be disposed on the rotary track mechanism and being rotated and continuously processed. Each of the plurality of the substrates can be sequentially exposed to two or more process gases delivered from a plurality of gas distribution assemblies positioned at a distance above the rotary track mechanism. In addition, two substrates are concurrently loaded and unloaded from the rotary track mechanism to save time and increase processing throughput.

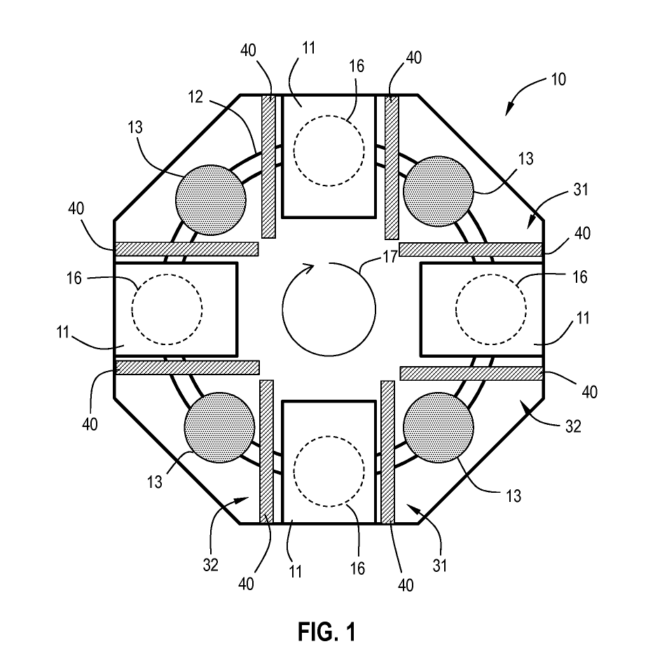

Processing chambers having multiple gas injectors can be used to process multiple wafers simultaneously so that the wafers experience the same process flow. As used in this specification and the appended claims, the terms “substrate” and “wafer” are used interchangeably to refer to a discrete, rigid material upon which processing (e.g., deposition, annealing, etching) is performed. For example, as shown in FIG. 1, the processing chamber has four gas injectors and four wafers. At the outset of processing the wafers can be positioned between the injectors. Rotating the carousel 45° will result in each wafer being moved to an injector for film deposition. An additional 45° rotation would move the wafers away from the injectors. With spatial ALD injectors, a film is deposited on the wafer primarily during movement of the wafer relative to the injector.

The processing chamber 10 shown in FIG. 1 is merely representative of one possible configuration and should not be taken as limiting the scope of the invention. Here, the processing chamber 10 includes a plurality of gas distribution assemblies 11. In the embodiment shown, there are four gas distribution assemblies 11 evenly spaced about the processing chamber 10. The processing chamber 10 shown is octagonal, however, it will be understood by those skilled in the art that this is one possible shape and should not be taken as limiting the scope of the invention.

The processing chamber 10 includes a substrate support apparatus 12 within the processing chamber 10. The substrate support apparatus 12 is capable of moving a plurality of substrates beneath each of the gas distribution assemblies 11. A load lock, not shown, might be connected to a side of the processing chamber 10 to allow the substrates to be loaded/unloaded from the chamber.

The processing chamber 10 includes a plurality, or set, of first treatment stations 13 positioned between each of the plurality of gas distribution assemblies 11. Each of the first treatment stations 13 provides the same treatment to a substrate. In some embodiments, as shown in FIG. 3, a set of second treatment stations 14 are positioned between the first treatment stations 13 and the gas distribution assemblies 11 so that a substrate rotated through the processing chamber 10 would encounter, depending on where the substrate starts, a gas distribution assembly 11, a first treatment station 13 and a second treatment station 14 before encountering a second of any of these. For example, as shown in FIG. 3, if the substrate started at the first treatment station 13, it would see, in order, the first treatment station 13, a gas distribution assembly 11 and a second treatment station 14 before encountering a second first treatment station 13.

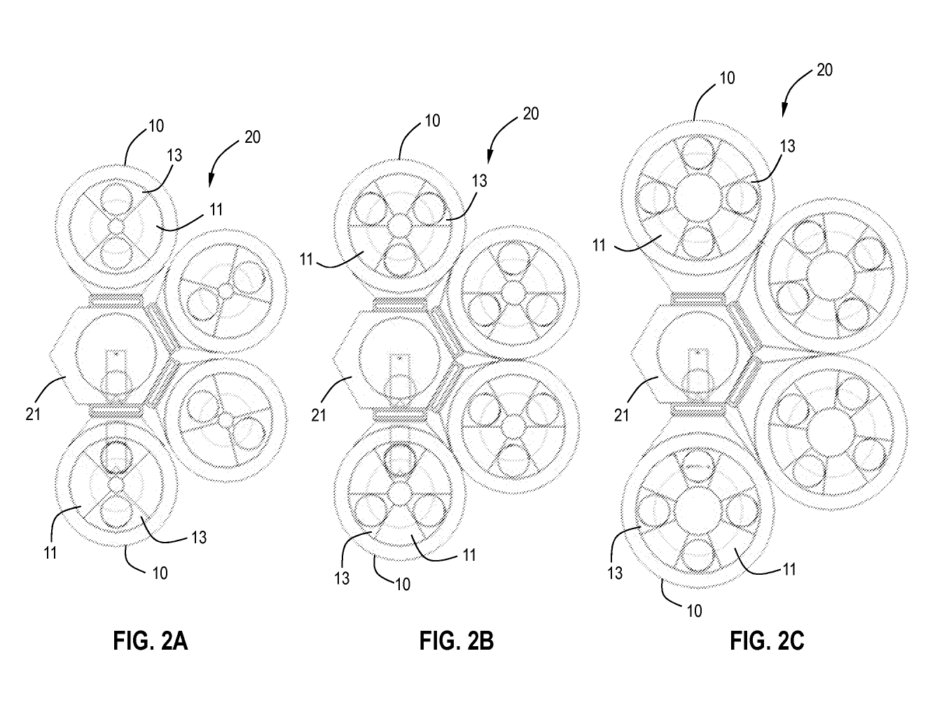

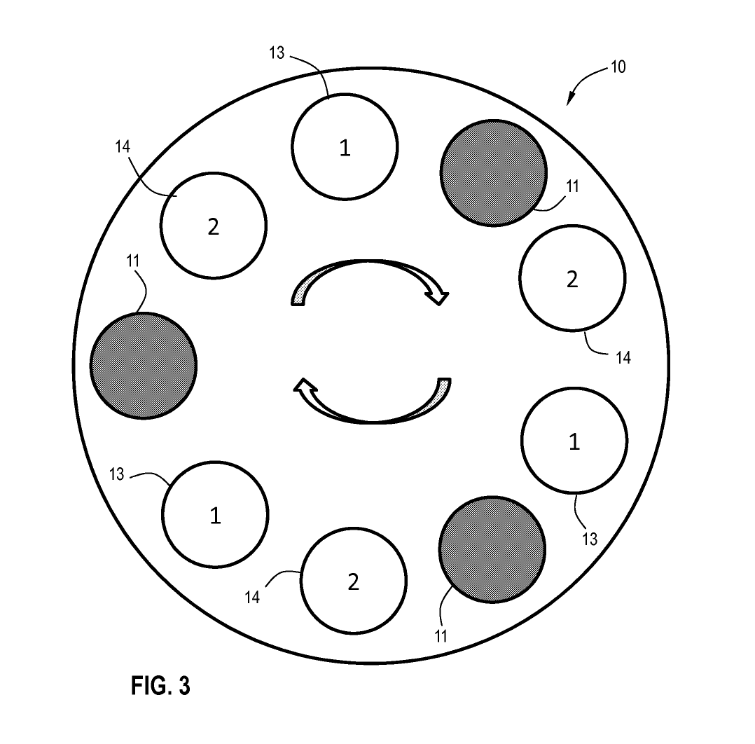

FIGS. 2A through 2C show different embodiments of cluster tools 20 with multiple carousel type processing chamber 10. The embodiment shown in FIG. 2A has four processing chambers 10 around a central transfer station 21. Each of the processing chambers 10 includes two gas distribution assemblies 11 and two first treatment stations 13. The embodiment of FIG. 2B has three gas distribution assemblies 11 and three first treatment stations 13 and the embodiments of FIG. 2C has four gas distribution assemblies 11 and four first treatments stations 13. Other numbers of injectors, or gas distribution assemblies, can be employed as well. In some embodiments, the number of injectors is equal to the number of wafers that can be processed simultaneously. Each wafer is either under the injector or in the region between the injectors so that each wafer has the same experience (i.e., experiences the same conditions) during processing.

Additional processing apparatus can also be positioned between the injectors. For example, US lamps, flash lamps, plasma sources and heaters. The wafers are then moved between positions with the injectors to a position with, for example, a showerhead delivering a plasma to the wafer. In one or more example, silicon nitride films can be formed with plasma treatment after each deposition layer. As the ALD reaction is, theoretically, self-limiting as long as the surface is saturated, additional exposure to the deposition gas will not cause damage to the film.

Rotation of the carousel can be continuous or discontinuous. In continuous processing, the wafers are constantly rotating so that they are exposed to each of the injectors in turn. In discontinuous processing, the wafers can be moved to the injector region and stopped, and then to the region between the injectors and stopped. For example, the carousel can rotate so that the wafers move from an inter-injector region across the injector (or stop adjacent the injector) and on to the next inter-injector region where it can pause again. Pausing between the injectors may provide time for additional processing steps between each layer deposition (e.g., exposure to plasma).

In some embodiments, there are a different number of wafers than injectors maintaining a symmetrical orientation. For example, a processing chamber can have three injectors and six wafers. Initially, none of the wafers are positioned under the injectors; rotation of the carousel 30° would place the first set of wafers under the injectors and move the second set of wafers into a position immediately preceding the injector. The next 30° rotation would move the first set of wafers out from under the injectors and the second set of wafers to the injector region. Again, the substrates can be exposed to additional processing steps between each injector.

The injectors can be substantially parallel (e.g., rectangular shaped) or wedge shaped. Once the surface reactions are saturated, it does not matter if the wafer spends additional time adjacent the injector as no additional reaction will occur.

In some embodiments, the processing chamber comprises a plurality of gas curtains 40. Each gas curtain 40 creates a barrier to prevent, or minimize, the movement of processing gases from the gas distribution assembly 11 from reaching the treatment station 13, and vice versa. The gas curtain 40 can include any suitable gases or vacuum streams which can isolate the individual processing sections from the adjacent sections. In some embodiments, the gas curtain 40 is a purge (or inert) gas stream. In one or more embodiments, the gas curtain 40 is a vacuum stream that removes gases from the processing chamber. In some embodiments, the gas curtain 40 is a combination of purge gas and vacuum streams so that there are, in order, a purge gas stream, a vacuum stream and a purge gas stream. In one or more embodiments, the gas curtain 40 is a combination of vacuum streams and purge gas streams so that there are, in order, a vacuum stream, a purge gas stream and a vacuum stream. The gas curtains 40 shown in FIG. 1 are positioned between each of the gas distribution assemblies 11 and treatment stations 13, but it will be understood that the curtains can be positioned at any point or points along the processing path of the rotary track mechanism 12.

Referring again to FIG. 1, one or more embodiments of the invention are directed to methods of processing a plurality of substrates. Each of the plurality of substrates 16 is loaded into the processing chamber 10 so that each substrate 16 is in an relatively identical position as the other substrates 16. As used in this specification and the appended claims, the term “relatively identical”, “relatively the same”, “substantially equal starting positions” and the like, mean that the substrates are in equivalent positions (e.g., each under a gas distribution assembly or each between gas distribution assemblies). For example, each substrate 16 in FIG. 1 is shown positioned under the gas distribution assembly 11. Therefore, each substrate 16 has substantially equal starting positions as the other substrates. The plurality of substrates are positioned on a substrate support apparatus 12 which may include a track portion and/or support structures. The substrate support apparatus 12 rotates the substrates 16 around in a circle 17, or similar shape. Upon rotation, the substrates 16 move from their initial position to a next position which may be under the first treatment stations 13. When the gas distribution assemblies 11 are spatial atomic layer deposition apparatus, like that shown and described in FIG. 7, the movement under the gas distribution assembly causes each portion of the substrate to be exposed to a series of process gases (also referred to as precursor gases or reactive gases, and the like) to deposit a layer on the substrate surface. The substrate then moves to the first treatment station 13 where it is subjected to a post-deposition process. In some embodiments, the post-deposition process is one or more of annealing and plasma treatment.

The substrates are moves either in a continuous uninterrupted manner or in discrete steps. When moved in discrete steps, the substrates may be moved from a first treatment station through the gas distribution assembly area to another first treatment station. This allows the movement of the substrate to cause the sequential exposure of the different reaction gases adjacent the gas distribution assembly to deposit the film.

In some embodiments, alternating gas distribution assemblies provide alternate reaction gases and the alternating first treatment stations provide a different treatment. For example, the first gas distribution assembly may supply a first reactive gas to the substrate surface to form a partial film on the surface, the substrate can then move to a first treatment station where the partial film is heated and then moved to the second gas distribution assembly where a second reactive gas reacts with the partial film to form a complete film followed by moving the substrate to another first treatment station where the film is exposed to a plasma to, for example, densify the film.

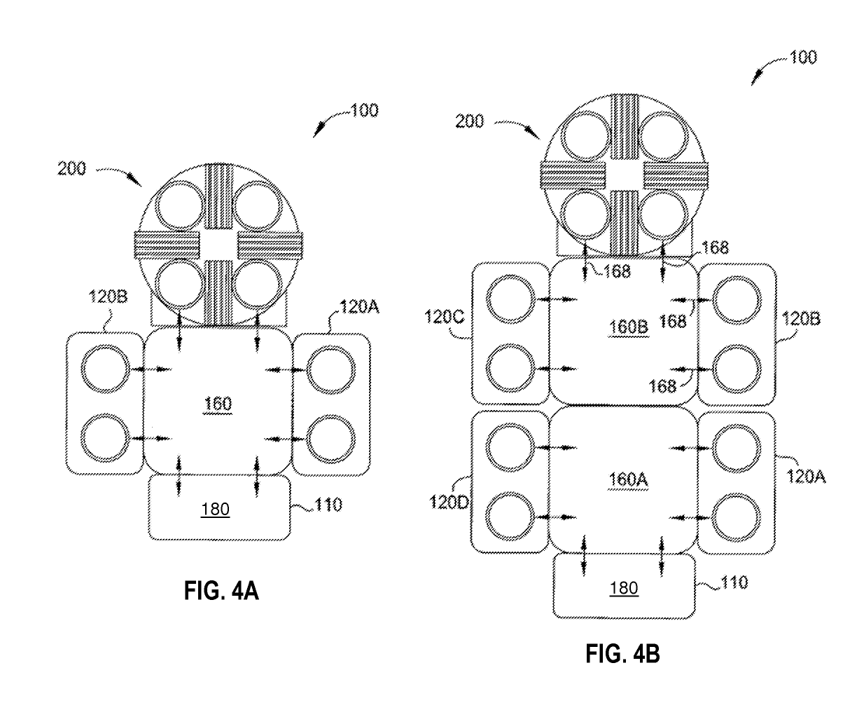

FIG. 4A is a schematic plan view of a substrate processing system 100 for continuous, multiple substrates processing. The substrate processing system may include a processing platform 200, a transfer chamber 160 connected to the processing platform 200, and, optionally, a substrate staging platform 180.

The processing platform 200 is designed for depositing a material layer over a plurality of substrates 210 in an ALD or CVD process. The processing platform 200 generally includes a substrate support assembly 275 (e.g., a carousel-like mechanism) having a multi-substrate receiving surface capable of supporting the plurality of the substrates 210. The substrate support assembly 275 can be supported and rotated by a rotary track mechanism or a rotary shaft disposed below.

Each substrate 210 may be supported by a substrate carrier 240 for ease of securing each substrate 210 on the substrate support assembly 275 during rotation. Alternatively, each of the plurality of substrates 210 may be supported by the substrate carrier 240, which can be in turn securely disposed on the rotary shaft or rotary track mechanism during substrate processing, and prevent the substrate 210 from being dislodged during the rational movement of the rotary track mechanism.

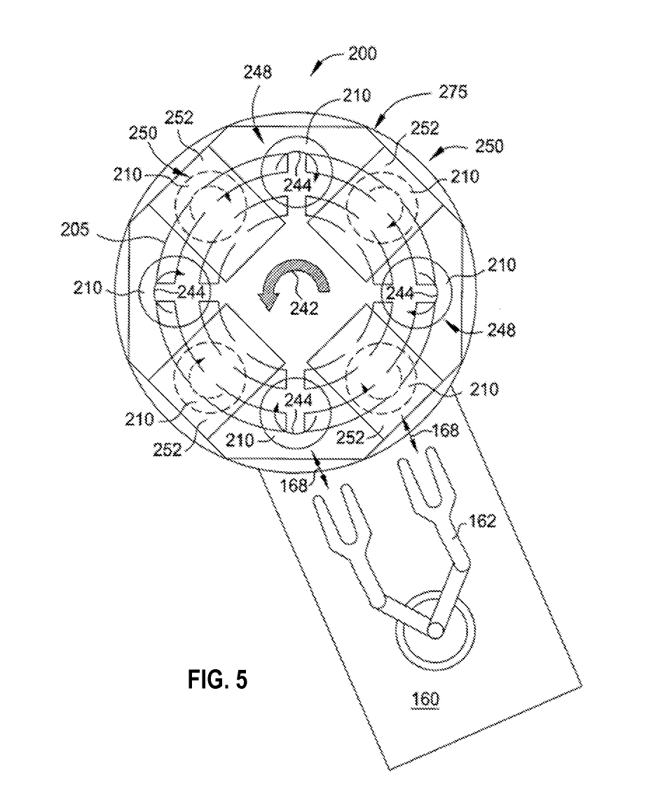

Two substrates 210 can be supported alone by a dual-blade robot (as shown in FIG. 5) and transferred from the transfer chamber 160 and loaded onto the substrate support assembly 275 within the processing platform 200. Alternatively, two substrates 210 can be carried on two substrate carries 240 and two substrate carriers 240 with two substrates there on can be transferred by the dual-blade robot, loaded on the substrate support assembly 270, and secured atop the substrate support assembly 275.

The staging platform 180 includes one or more dual-substrate processing stations 120A, 1208, suitable for preparing two substrates 210 prior to the ALD or CVD process, and/or performing pre-deposition, post-deposition substrate treatments. In addition, the staging platform 180 may include additional process chambers for other CVD, PVD, etch, cleaning, heating, annealing, and/or polishing processes. The substrate processing system 100 may include load luck chamber (e.g., a dual-substrate load luck chamber 110). In general, a low-contamination clean environment is maintained within the substrate processing system 100.

FIG. 4B is a schematic plan view of another example of the substrate processing system 1 00 configured with the processing platform 200 and the staging platform 180. The staging platform 180 may include, for example, two transfer chambers 160A, 1608 and four dual-substrate processing stations 120A, 1208, 120C, 1200, and additional chambers for continuously multi-substrate processing, where two substrates can be loaded and/or unloaded onto and out of the processing platform 200.

The four dual-substrate processing stations 120A, 1208, 120C, 120, within the staging platform 120 may be a pre-treatment station, a post-treatment station, and stations for different processes (e.g., plasma treatment, annealing, etc.).

FIG. 5 is a schematic plan view of the processing platform 200 with multiple shower head stations 250. The processing platform 200 is connected to the transfer chamber 160, having a dual blade robot 162 disposed therein for transferring two substrates in and out of the processing platform 200. Optionally multiple buffer stations 248 are disposed in-between the shower head stations 250 for spatially separating each shower head station 250 and/or conducting substrate heating or curing of the films deposited over the surface of the substrates 210.

As shown in FIG. 5, a plurality of the substrates 210 can be rotationally disposed below the gas distribution assemblies 252 of the multiple shower head stations 250. During substrate processing, the rotary track mechanism 245 or the shaft below the substrate support assembly 275 is configured to rotate in the horizontal direction 242 (e.g., clockwise or counterclockwise) at a first rotating speed (e.g., from zero to less than 30 rpm) such that the plurality of substrates 210 are rotated under and passed through each of the shower head stations 250 and the buffer stations 248.

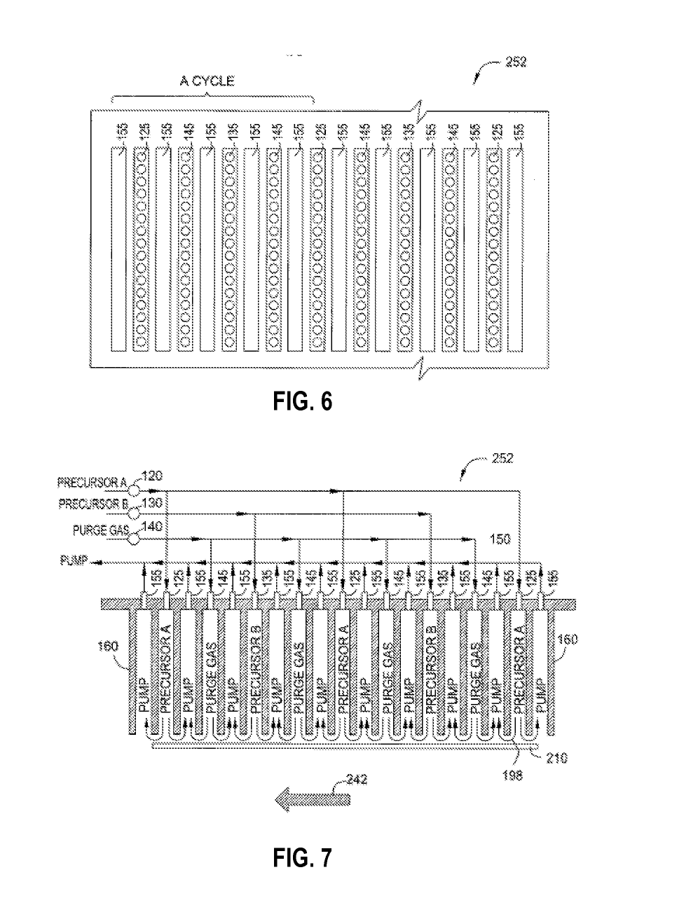

FIG. 6 illustrates a side view of the gas distribution assembly 252 in a shower head station 250, the side facing the surface of the substrate 210. FIG. 7 is a partial cross-sectional side view of the gas distribution assembly 252 with the substrate 210 disposed below.

The gas distribution assembly 252 may include multiple gas channels 125, 135, 145, with multiple openings facing the surface of the substrate 210 for delivery of precursor gas A, precursor gas 8, and purge gas, from gas boxes 120, 130, 140, respectively. Multiple gas channels 155 are connected to a pumping system and provided for pumping excess gasses out of the processing space above the surface of the substrate 210. In one embodiment, the gas channels 125, 135, 145, 155 are spatially separated and alternatively disposed across a horizontal plane of the gas distribution assembly 252. In another embodiment, precursor gas A, precursor gas B, and purge gas are continuously flown into the gas channels 125, 135, 145, 155 and onto different locations over the surface of the substrate 210. Each gas channel 125, 135 is provided for delivery of a gas flow a precursor compound from to be chemi-absorbed over the surface of the substrate 210 when the substrate is rotated and arrived below each gas channel 125, 135.

Each gas channel 145 is provided for delivery of a gas flow of a purge gas to separate each flow of the precursor A and precursor B over the surface of the substrate 210 when the substrate is rotated and arrived below the gas channel 145. Accordingly, each substrate 210 may be exposed to precursor gas A, precursor gas B, and purge gas simultaneously, but at different locations, when disposed under the openings of the multiple gas channels 125, 135, 145, which are spatially separated within each gas distribution assembly 252.

Referring back to FIG. 1, additional embodiments of the invention are directed methods of processing a plurality of substrates 16. The plurality of substrates 16 are loaded onto a rotary track mechanism 12 in a processing chamber 10 which includes a plurality of gas distribution assemblies 11. The substrates 16 are rotationally disposed about the interior of the processing chamber 10 adjacent the rotary track mechanism 12 and in substantially equivalent starting positions (e.g., each substrate is positioned on a first side of an adjacent gas distribution assembly 11) so that from the perspective of the substrates 16, each is in the same position. The rotary track mechanism 12 is rotated so that each substrate 16 moves from a first side 31 of a gas distribution assembly 11 beneath the gas distribution assembly 11 to a second side 32 of the gas distribution assembly 11. A layer is deposited on the surface of the substrate 16 by a plurality of gas streams provided by the gas distribution assemblies 11, as described with respect to FIGS. 6 and 7. The rotary track mechanism is repeatedly or continuously rotated so that each substrate 16 moves from the first side 31 of a gas distribution assembly to the second side 32 of the gas distribution assembly 11 and then further toward the first side 31 of the next gas distribution assembly 11. This is continued until a film of desired thickness is formed. Once the film thickness has been formed, the plurality of substrate are removed from the processing chamber so that each substrate has experienced substantially the same processing environment (e.g., each has passed beneath the same number of gas distribution assemblies and/or each has passed beneath the same number of gas distribution assemblies the same number of times).

In some embodiments, movement of the rotary track mechanism 12 is stopped after each substrate 16 has passed to the second side 32 of the gas distribution assembly 11 so that each substrate 16 is positioned adjacent a treatment station 13 which provides a plasma treatment of the film formed on the surface of the substrate 16. The rotary track mechanism 12 can be stopped and started any number of times so that each substrate passes beneath a gas distribution assembly followed by plasma treatment of the film deposited by the gas distribution assembly.

In one or more embodiments, the rotary track mechanism rotates the substrates through a gas curtain 40 positioned between before and/or after each of the gas distribution assemblies. This gas curtain 40 can include a purge gas stream entering the processing chamber 10 and/or a vacuum stream exiting the processing chamber 10. In some embodiments, both a purge gas stream and a vacuum stream are employed so that there is, in order, a purge gas stream, a vacuum stream and a purge gas stream separating each of the gas distribution assemblies from the adjacent treatment station 13.

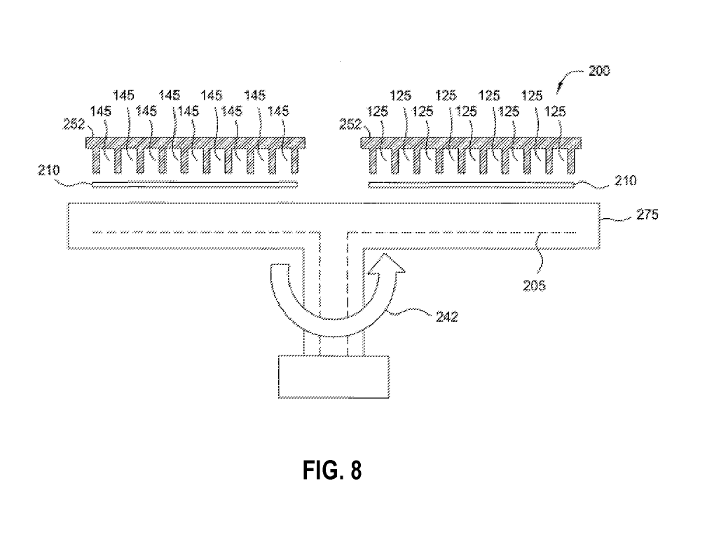

FIG. 8 is a partial cross-sectional side view of the processing platform 200, showing two substrates 210 disposed below two gas distribution assemblies 252 of two processing stations 250 on the surface of a rotary substrate support assembly 275. As shown in FIG. 5, a portion of a substrate may be exposed to multiple flows of precursor gas A via the openings of the gas channel 125, while a portion of another substrate may be exposed to multiple flows of purge gas via the openings of the gas channel 145.

In addition, the process temperature and pressures within the processing platform 200 are controlled at levels suitable for an ALD or CVD process. For example, one or more pumps may be disposed inside the processing platform 200 and one or more heater system 205 may be disposed below the substrate support assembly 275. Additional heating systems may include radiant or convective heating from top or bottom of the substrate support assembly 275. In addition, the processing platform can be coupled to local or remote plasma source for conducting plasma enhanced atomic layer deposition (PEALD) process within the processing system 100.

In operation, for depositing a tantalum nitride (TaN) material layer over a surface of the substrate 210, two precursor compounds may be used. The first precursor may be a tantalum containing compound, such as a tantalum based organo-metallic precursor or a derivative thereof, e.g., pentadimethylamino-tantalum (PDMAT; Ta(NMe₂)₅), pentaethylmethylamino-tantalum (PEMAT; Ta[N(C₂H₅CH₃)₂]₅), pentadiethylamino-tantalum (PDEAT; Ta(NEt₂)s,), TBTDET (Ta(NEt₂)₃NC₄H₉ or C₁₆H₃₉N₄Ta) and tantalum halides, and any and all of derivatives of the above listed compounds. The tantalum containing compound may be provided as a gas or may be provided with the aid of a carrier gas. Examples of carrier gases which may be used include, but are not limited to, helium (He), argon (Ar), nitrogen (N₂), and hydrogen (H₂).

After the delivery of the first precursor gas (precursor gas A) into the processing region 280 of the batch processing chamber 200, a monolayer of the tantalum containing compound is chemisorbed onto the surface of the substrate 210 and excess tantalum containing compound is removed from the process chamber by introducing a pulse of a purge gas thereto. Examples of purge gases which may be used include, but are not limited to, helium (He), argon (Ar), nitrogen (N₂), hydrogen (H₂), and other gases.

After the process chamber has been purged, a second precursor gas (precursor gas B) may be delivered into the processing regions 280 of the batch processing chamber 200. The second precursor may be a nitrogen containing compound with nitrogen atoms and one or more reactive atoms/species. For example, the nitrogen containing compound may be ammonia gas (NH3) and other nitrogen containing compounds, including, but not limited to, NₓH_{y} with x and y being integers (e.g., hydrazine (N₂H₄)), dimethyl hydrazine ((CH₃)₂N₂H₂), t-butylhydrazine (C₄H₉N₂H₃) phenylhydrazine (C₆H₅N₂H₃), other hydrazine derivatives, a nitrogen plasma source (e.g., N₂, N₂/H₂, NH₃, or a N₂H₄ plasma), 2,2′-azoisobutane ((CH₃)₆C₂N₂), ethylazide (C₂H₅N₃), and other suitable gases. The nitrogen containing compound may be introduced into the processing region 280 as a pulse, and may be provided alone. Alternatively, a carrier gas may be used to deliver the nitrogen containing compound if necessary.

After the delivery of the second precursor gas (precursor gas A) into the processing region 280 of the batch processing chamber 200, a monolayer of the nitrogen containing compound may then be chemisorbed on the monolayer of the tantalum containing compound. The composition and structure of precursors on a surface during atomic-layer deposition (ALD) is not precisely known. Not wishing to be bound by theory, it is believed that the chemisorbed monolayer of the nitrogen containing compound reacts with the monolayer of the tantalum containing compound to form a tantalum nitride layer. Reactive species from the two precursor compounds may form by-products that are transported from the substrate surface (e.g., via the fluid outlets 262 and the exhaust system 260). It is believed that the reaction of the nitrogen containing compound with the tantalum containing compound is self-limiting and, in each pulse of delivering a precursor compound into the processing region 280, only one monolayer of the precursor compound is chemisorbed onto the surface of the substrate 210. Each cycle of the sequential delivery of the two or more alternating precursors over the surface of the substrate is repeated (e.g., 20-30 cycles) until a desired thickness of the material layer (e.g., a tantalum nitride film) is formed.

A fluid delivery system may be in fluid communication with the internal process volume below each of the gas distribution assemblies 250 and may be positioned in a facilities tower proximate the processing platform 200. A management or system control system is connected to the processing platform 200 and/or the multi-chamber substrate processing system 100 for controlling the process performed inside the processing platform 200.

While the foregoing is directed to embodiments of the present invention, other and further embodiments of the invention may be devised without departing from the basic scope thereof, and the scope thereof is determined by the claims that follow.

1. A substrate processing platform for processing a plurality of substrates, the substrate processing platform comprising:
one or more gas distribution assemblies;
a rotary track mechanism, positioned at a first distance below the one or more gas distribution assemblies to receive the plurality of substrates supported by a plurality of substrate support carriers disposed thereon; and
a dual-blade transfer robot capable of carrying two substrates and concurrently transferring the two substrates onto and out of two substrate carriers disposed on the rotary track mechanism,
wherein the rotary track mechanism is capable of concurrently receiving at least two substrates and to rotate at a first rotating speed such that the plurality of substrates disposed on the plurality of substrate carriers are rotated under and passed through the one or more gas distribution assemblies.

2. The substrate processing platform of claim 1, wherein each substrate carrier disposed on the rotary track mechanism self-rotates at a second rotating speed.

3. The substrate processing platform of claim 1, further comprising one or more buffer stations rotationally disposed between the one or more gas distribution assemblies.

4. The substrate processing platform of claim 1, further comprising one or more treatment stations rotationally disposed between the one or more gas distribution assemblies.

5. The substrate processing platform of claim 4, wherein the one or more treatment stations comprise plasma processing stations.

6. The substrate processing platform of claim 1, wherein there are two or more gas distribution assemblies rotationally disposed adjacent the rotary track mechanism.

7. The substrate processing platform of claim 6, further comprising a set of first treatment stations and a set of second treatment stations, so that a first treatment station and a second treatment station are rotationally positioned adjacent the rotary track mechanism between each of the gas distribution assemblies.

8. A substrate processing system for processing a plurality of substrates, the substrate processing system comprising:
the processing platform of claim 1; and
a transfer chamber having a dual-blade transfer robot capable of carrying two substrates and concurrently transferring the two substrates onto and out of two substrate carriers disposed on the rotary track mechanism.

9. The substrate processing system of claim 8, wherein each substrate carriers disposed on the rotary track mechanism is capable of self-rotating at a second rotating speed.

10. The substrate processing system of claim 8, wherein the processing platform further comprises one or more buffer stations rotationally disposed between the one or more gas distribution assemblies.

11. The substrate processing system of claim 8, further comprising one or more treatment stations rotationally disposed between the one or more gas distribution assemblies.

12. The substrate processing system of claim 11, wherein the one or more treatment stations comprise plasma processing stations.

13. The substrate processing system of claim 8, wherein the processing platform comprises two or more gas distribution assemblies rotationally disposed adjacent the rotary track mechanism.

14. The substrate processing system of claim 13, further comprising a set of first treatment stations and a set of second treatment stations, so that a first treatment station and a second treatment station are rotationally positioned adjacent the rotary track mechanism between each of the gas distribution assemblies.

15. The substrate processing system of claim 8, further comprising a staging platform having at least one dual-substrate processing station configured for concurrently processing two substrates therein.

16. A method of processing a plurality of substrates, the method comprising:
loading a plurality of substrates onto a rotary track mechanism in a processing chamber comprising a plurality of gas distribution assemblies so that the substrates are rotationally disposed about the interior of the processing chamber adjacent a rotary track mechanism and positioned in substantially equivalent starting positions;
rotating the rotary track mechanism so that each substrate moves from a first side of a gas distribution assembly to a second side of the gas distribution assembly so that layer is deposited on a surface of the substrate by a plurality of gas streams provided by the gas distribution assembly;
continuing to rotate the rotary track mechanism so that each substrate moves from the first side of a gas distribution assembly to the second side of the gas distribution assembly until a film of desired thickness is formed; and
unloading the plurality of substrates from the processing chamber so that each substrate has experienced substantially the same processing environment.

17. The method of claim 16, further comprising stopping the rotary track mechanism after each substrate has passed to the second side of the gas distribution assembly so that each substrate is positioned adjacent a plasma treatment station and plasma treating the film formed on the surface of the substrate.

18. A method for batch processing a plurality of substrates, the method comprising:
loading two of the plurality of substrates onto a rotary track mechanism of a batch processing platform;
continuously rotating the rotary track mechanism such that the plurality of the substrates are moved under and passed through one or more gas distribution assemblies positioned at a first distance above the rotary track mechanism; and
unloading the two substrates from the rotary track mechanism of the batch processing platform.

19. The method of claim 18, wherein the plurality of substrate are disposed on two substrate carriers disposed on the rotary track mechanism.

20. The method of claim 18, wherein two of the plurality of substrates are loaded using a dual-blade transfer robot that can carry and concurrently transfer the two substrates onto and out of the rotary track mechanism.
